(19) United States
(12) Patent Application Publication
(10) Pub. No.: US 2015/0014048 A1
(43) Pub. Date: Jan. 15, 2015

(54) SATELLITE SURVEILANCE INSULATION

(71) Applicant: Kelvin Berrman Harrison, Los Angeles, CA (US)

(72) Inventor: Kelvin Berrman Harrison, Los Angeles, CA (US)

(21) Appl. No.: 14/330,385

(22) Filed: Jul. 14, 2014

Related U.S. Application Data
(60) Provisional application No. 61/845,610, filed on Jul. 12, 2013.

(51) Int. Cl. H05K 9/00; E04B 1/92

(52) U.S. Cl. CPC H05K 9/0075; E04B 1/92; H05K 9/0001
USPC 174/350; 228/110.1; 156/71

(57) ABSTRACT

An electromagnetic interference shield used in room construction materials for the protection from satellite surveillance that has a first surface, a second surface where the first surface and the second surface are configured to attach to each other and where the first surface and the second surface are separable from each; a third surface where the second surface and the third surface are configured to attach to each other and where the second surface and third surface are separable from each other; a fourth surface where the third surface and fourth surface are configured to attach to each other and where the third surface and fourth surface are separable from each other.

### CROSS-REFERENCE TO RELATED APPLICATION

This Non-Provisional Patent Application claims priority to U.S. Provisional Utility Application Ser. No. 61/845,610 filed Jul. 12, 2013, the contents of which are incorporated by this reference.

### FIELD OF THE INVENTION

The present invention relates to the field of satellite surveillance insulation to protect the home from electromagnetic interference (EMI), and to a method of using the insulation.

### BACKGROUND OF THE INVENTION

Surveillance satellites are well known. Surveillance satellites are commonly used to provide tactical advantages and to gather intelligence on people. For example, surveillance satellites can provide images that show terrain, troop disbursements, convoys, and the location of artillery, missiles, aircraft and other equipment. In addition, surveillance satellites can be used to track non-combat citizens in times of peace.

Electromagnetic compatibility (EMC) is a broad term used to describe electromagnetic interference (EMI), radio frequency interference (RFI) and electrostatic discharge (ESD), and the above terms are often used interchangeably.

A variety of conventional techniques are employed as the methods of EMI-shielding. Among these are the following: (1) a method wherein paint using a conductive material, e.g., silver or copper, as a filler, is applied to an enclosure after the molding of the enclosure, (2) a flame spraying method wherein the conductive material, e.g., silver or copper, is fused and sprayed to an enclosure by high-pressure air, (3) a vacuum metallizing method wherein metal of low boiling point (such as aluminum) is evaporated in a vacuum to form a thin film on enclosure surfaces, (4) a method wherein electroless plating of nickel, etc., is provided to an enclosure molded by high-adhesive resin, e.g., ABS resin, (5) a method wherein a molding material filled with a conductive filler, such as carbon or aluminum flakes, is used to mold an enclosure, and (6) a method wherein a composite material made by laminating a polyvinyl chloride (PVC) or polyester film to an aluminum, copper or other film is applied to an enclosure.

Today, plastics are replacing metals as the material for electronic enclosures since plastics offer increased design flexibility and productivity with decreased cost. The switch from metal to plastics as a housing material for electronic equipment has contributed to concern over EMI shielding. Plastics are insulators, so EMI waves pass freely through unshielded plastic without substantial impedance or resistance. Additionally, ever increasing device miniaturization and the increase in clock speeds of microprocessors used in computing devices makes it more difficult to handle the EMI pollution these faster computers generate. So a variety of technologies using metal/polymer combinations and composites are being used as a shielding material in electronic devices.

Current methods for shielding of electromagnetic interference (EMI) include the use of metal housings, metal filled polymer housings, metal liners for housings, and conductive coatings for the interior of rigid polymer or composite housings.

Metal coatings for rigid plastic housings are applied through use of conductive paints or through application of metal platings applied by chemical plating (electroless plating), by electroplating, or through vacuum metallization. In addition, metal foils with adhesive backings may be applied to the inside of plastic cases for electronic instruments to achieve shielding requirements. Zinc Arc spray techniques are also available to apply a metal coating to a plastic housing.

The fact that surveillance satellites can track and gather communication is a problem. As a result, there is a need for insulation for roof tops denying imaging and intelligence gathering capabilities to surveillance satellites.

### SUMMARY OF THE INVENTION

The present invention addresses the above stated need by providing an inexpensive apparatus wherein the use of layers to prevent satellite surveillance is used.

A room protection or full home roof protection, may be used as addition to construction roofing and non window rooms for protection against modern airborne satellite cyber surveillance tactics by private and government aerospace industries.

It may be further used to protect privacy of celebrities and government officials or royal families or for the very wealthy or for anyone that can afford the construction costs.

The insulation mainly constructed in the roof of a home from space surveillance into a home from motion surveillance of an individual in his home.

The materials used to construct a sandwich like large slab made in sections and inserted into the wall and roof to become as a large one piece section.

These and other objects of the present invention will become readily apparent upon further review of the following specification and drawings.

### BRIEF DESCRIPTION OF THE DRAWINGS

Various objects, features, and attendant advantages of the present invention will become more fully appreciated as the same becomes better understood when considered in conjunction with the accompanying drawings, in which like reference characters designate the same or similar parts throughout the several views, and wherein:

FIG. 1 is a perspective view of the satellite surveillance prevention aspect of the invention.

FIG. 2 is a representation of the different layers involved with the invention.

FIG. 3 is a method of using the invention.

### DETAILED DESCRIPTION

While the present invention has been described in connection with what is considered the most practical and preferred embodiment, it is to be understood that the present invention is not to be limited to the disclosed arrangements, but is intended to cover various arrangements which are included within the spirit and scope of the broadest possible interpretation of the appended claims so as to encompass all modifications and equivalent arrangements which are possible.

Reference will now be made in detail to various exemplary embodiments of the invention. The following detailed description is presented for the purpose of describing certain embodiments in detail. The present invention may be further illustrated in the following figures, attention being called to the fact, however, that the embodiments described in the description and shown in the figures are illustrative only and are not intended to limit the scope of the invention, and that changes may be made in the specific constructions described in this specification and accompanying drawings that a person of ordinary skill in the art will recognize are within the scope and spirit of the invention. The true scope of the invention is defined by the claims. Further, any features of any embodiment described herein are equally applicable to any other embodiment described herein or envisioned by one of ordinary skill in the art. The detailed description and figures provided herein should not be construed to exclude features otherwise described with respect to another embodiment.

Although, the present application refers to the electromagnetic interference shield apparatus 100 in terms of roofing, the invention may be employed on or in walls or floor surfaces. As such, roof, walls, floor, and any other variations thereof may be collectively referred to as “room construction materials.” Moreover, the terms, roof, walls, or room construction materials may be used interchangeably for the purposes of this application.

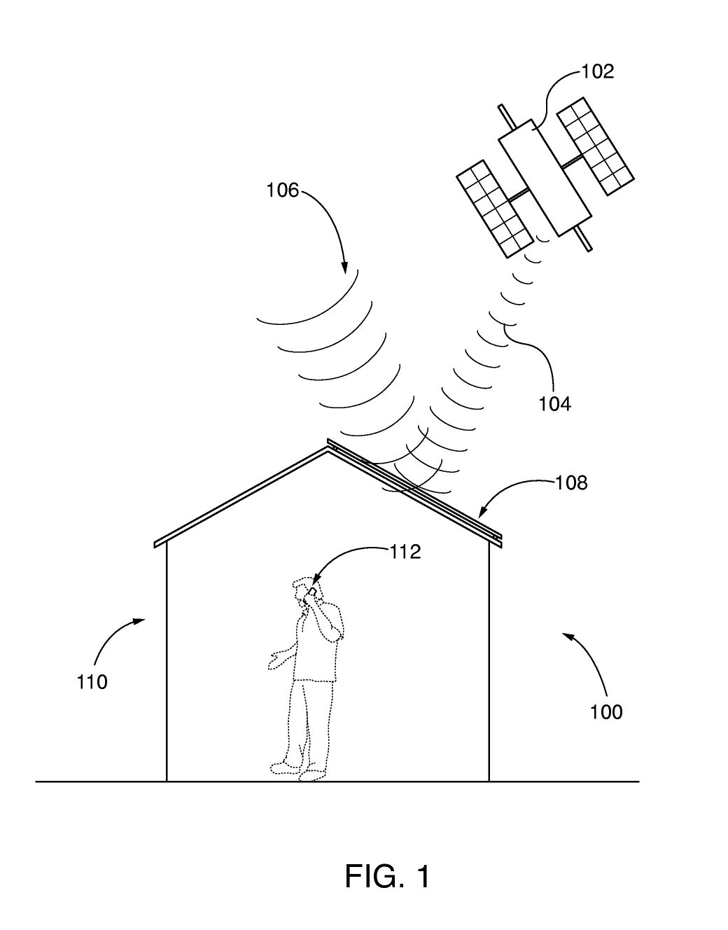

Referring now to FIG. 1, an embodiment of an electromagnetic interference shield apparatus 100 is depicted. The apparatus 100 may include an electromagnetic interference shield or some sort of collection of layers of materials 108, a house 110 or some sort of building, and a roof that is located on top of the building that has the collection of layers of materials attached on top of the roof.

As a non-limiting example, the electromagnetic interference shield used in roof construction for the protection from satellite surveillance may be made up of a first surface, a second surface where the first surface and the second surface are configured to attach to each other. Furthermore, the first surface and the second surface are separable from each other. A third surface and the second surface are configured to attach to each other. Just like the first and second surface, the second surface and third surface are separable from each other. A fourth surface and the third surface previously discussed may be configured to attach to each other. The third surface and fourth surface are separable from each other as well.

As seen in FIG. 1, a satellite 102 may be used to gather intelligence from the citizen population. One way this is achieved is by sending electromagnetic interference signals 104 to the general population. Electromagnetic compatibility (EMC) is a broad term used to describe electromagnetic interference (EMI), radio frequency interference (RFI) and electrostatic discharge (ESD), and the above terms are often used interchangeably and will so be used in the present application.

When the EMI signal is sent to a house 110, if the roof has the shield 108 installed, then the signal would either be bounced 106 or absorbed by the layers. This would result in the satellite 102 not being able to be read the signal sent out originally. As a result, the person using a device such as a cell phone 112 or computer or even a conversation would enjoy his or her privacy.

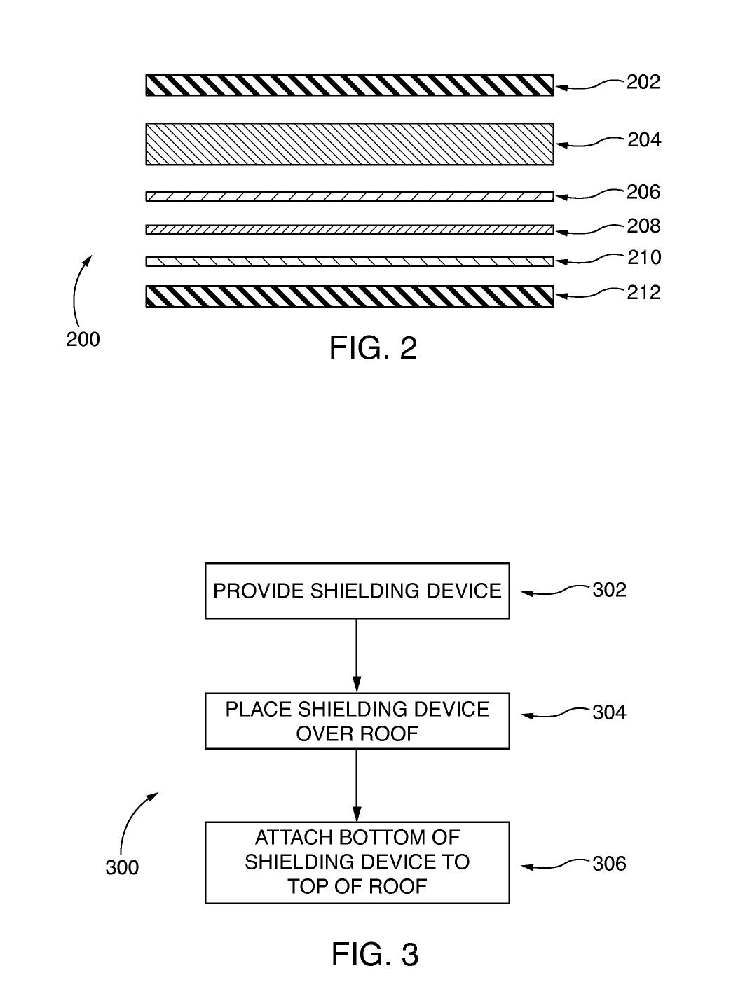

Now referring to FIG. 2, the roof construction may be a magnet material 204 wherein the magnet material 204 is made into large thin sheets. The magnetic material 204 may be coated in rubber coating 202. This could not only add to the durability of the invention but also it could insulate the invention. Moreover, the magnetic material 204 may be coated in plastic coating. Just like the rubber coating mentioned previously, the durability of the invention can be improved but also it could insulate the invention

Furthermore, the second surface may be comprised of lead sheet 206 that is added to a construction wherein the second surface may be the inner core of a sandwich combination. The third surface may be comprised of aluminum sheet 208 that is added to a construction wherein the third surface is the inner core of a sandwich combination.

The fourth surface may be comprised of titanium sheet 210 that is added to a construction wherein the fourth surface is the inner core of a sandwich combination wherein said fourth surface is placed below said third surface.

The layers 200 may be held together by sonic welding. The titanium sheet 210 may be coated in rubber coating 212. The titanium sheet 210 may be coated in plastic coating.

As a non-limiting example, the apparatus may be used in other applications in order to EMI waves from entering human bodies. The EMI insulation may be used in different applications such as clothing like shirts, pants, jackets, hats, sock, and other articles of clothing.

Now referring to FIG. 3, a method of electromagnetic interference shielding 300 may be used in roof construction for the protection from satellite surveillance comprising steps of obtaining a shielding device where a first surface, a second surface where the first surface and second surface are configured to attach to each other and where the first surface and second surface are separable from each other 302.

A third surface where the second surface and the third surface are configured to attach to each other and wherein the second surface and the third surface are separable from each other.

A fourth surface where the third surface and the fourth surface are configured to attach to each other and where the third surface and the fourth surface are separable from each other. Furthermore, the shielding device is placed on top of a roof 304.

The last step is attaching the bottom of the shielding device to the top of the roof. The method maybe be further comprised of welding the layers together by sonic welding.

As a non-limiting example, one room protection or full home roof protection may be used as addition to construction roofing and non window rooms for protection against modern airborne satellite cyber surveillance tactics by private and government aerospace industries.

As a non-limiting example, the invention may be used to protect the privacy of celebrities and government officials or royal families or for the very wealthy or for anyone that can afford the construction costs.

The insulation may be constructed in the roof of a home from space surveillance into a home from motion surveillance of an individual in his home. The materials used to construct a sandwich like large slab made in sections and inserted into the wall and roof to become as a large one piece section.

The materials may be comprised of an outer core. Magnet material made in large thin sheets coated in rubber plastic like coating. An example would be like using magnet strips that is used on appliances such as refrigerator for pictures or reminder notes. Thin sheet of lead as inner core to the sandwich construction. Aluminum sheet also added to inner core of sandwich combined construction. Titanium sheet added to inner core of sandwich combined construction. Last an Outer Plastic Rubber type coating may be applied.

The invention may be a privacy tool, blinds role up window covers, may be used in construction of roof under shingles. There is a possibility of making shingles or siding material out of it. The layers may be sandwiched held together by glue or sonic welding or any other method.

While the present invention has been described in connection with what is considered the most practical and preferred embodiment, it is to be understood that the present invention is not to be limited to the disclosed arrangements, but is intended to cover various arrangements which are included within the spirit and scope of the broadest possible interpretation of the appended claims so as to encompass all modifications and equivalent arrangements which are possible.

I claim:

1. An Electromagnetic Interference shield used in room construction materials for the protection from satellite surveillance comprising:
a first surface;
a second surface wherein said first surface and said second surface are configured to attach to each other and wherein said first surface and said second surface are separable from each other;
a third surface wherein said second surface and said third surface are configured to attach to each other and wherein said second surface and said third surface are separable from each other; and
a fourth surface wherein said third surface and said fourth surface are configured to attach to each other and wherein said third surface and said fourth surface are separable from each other.

2. The room construction materials of claim 1 wherein the first surface is a magnet material, wherein said magnet material is made into large thin sheets.

3. The room construction materials of claim 2 wherein said magnetic material is coated in rubber coating.

4. The room construction materials of claim 2 wherein said magnetic material is coated in plastic coating.

5. The room construction materials of claim 1 wherein the second surface is comprised of lead sheet that is added to a construction wherein the second surface is the inner core of a sandwich combination.

6. The room construction materials of claim 1 wherein the third surface is comprised of aluminum sheet that is added to a construction wherein the third surface is the inner core of a sandwich combination.

7. The room construction materials of claim 1 wherein the fourth surface is comprised of titanium sheet that is added to a construction wherein the fourth surface is the inner core of a sandwich combination wherein said fourth surface is placed below said third surface.

8. The room construction materials of claim 1 wherein the layers are held together by sonic welding.

9. The room construction materials of claim 7 wherein said titanium sheet is coated in rubber coating.

10. The room construction materials of claim 7 wherein said titanium sheet is coated in plastic coating.

11. A method of Electromagnetic Interference shielding used in room construction materials for the protection from satellite surveillance comprising steps of:
obtaining a shielding device comprising:
a first surface;
a second surface wherein said first surface and said second surface are configured to attach to each other and wherein said first surface and said second surface are separable from each other;
a third surface wherein said second surface and said third surface are configured to attach to each other and wherein said second surface and said third surface are separable from each other; and
a fourth surface wherein said third surface and said fourth surface are configured to attach to each other and wherein said third surface and said fourth surface are separable from each other;
placing said shielding device on top of a roof; and
attaching the bottom of said shielding device to the top of said roof.

12. The method according to claim 11, further comprising welding said layers together by sonic welding.
